(19) United States
(12) Patent Application Publication
(10) Pub. No.: US 2003/0169887 A1
(43) Pub. Date: Sep. 11, 2003

(54) Reverberation generating apparatus with bi-stage convolution of impulse response waveform

(75) Inventors: Hiroaki Fujita, Hamamatsu-shi (JP); Kiyoto Kuroiwa, Fukuroi-shi (JP); Kenichi Tamiya, Hamamatsu-shi (JP); Satoshi Sekine, Hamamatsu-shi (JP)

Correspondence Address: Roger R. Wise, Pillsbury Winthrop LLP, Suite 1200, 725 South Figueroa Street, Los Angeles, CA, 90017-5443, US

(73) Assignee: Yamaha Corporation, Hamamatsu-shi (JP)

(21) Appl. No.: 10/383,845

(22) Filed: Mar. 7, 2003

(30) Foreign Application Priority Data
Mar. 11, 2002 (JP) 2002-065694
Mar. 12, 2002 (JP) 2002-067556

(51) Int. Cl. H03G 3/00

(52) U.S. Cl. 381/63; 381/61

(57) ABSTRACT

A reverberation generating apparatus is designed for applying a reverberation effect to an acoustic signal for output based on sampling data representative of an impulse response waveform. In the apparatus, a first convolution operating section convolutes the acoustic signal with sampling data corresponding to an initial period of the impulse response waveform so as to generate an initial acoustic signal. The initial period of the impulse response waveform is determined from a point of impulse sound emission to a point after a lapse of a specified time. A second convolution operating section convolutes the acoustic signal with sampling data corresponding to a selected period of the impulse response waveform so as to generate an additional acoustic signal. An attenuation operating section recurrently outputs the additional acoustic signal while attenuating the additional acoustic signal so as to generate a late acoustic signal. An output section synthesizes the initial acoustic signal and the late acoustic signal for the output.

### BACKGROUND OF THE INVENTION

1. Technical Field of the Invention

The present invention relates to a technology to provide an acoustic signal with a reverberation effect of acoustic space.

2. Prior Art

There is available a reverberation generating apparatus that records an impulse response waveform in an acoustic space such as a hall or a church, convolutes an acoustic signal with sampling data of this impulse response waveform, and provides effects of an initial reflection sound and a succeeding reverberant sound as if observed in the acoustic space.

In order to obtain sampling data of the impulse response waveform in the acoustic space, a microphone or the like is used to collect and measure an acoustic signal such as an impulse sound and a TSP (Time Stretched Pulse) generated from a sound source placed in the acoustic space. Thereafter, the reverberation generating apparatus samples an analog signal waveform of a sound to be processed, converts the same into a digital signal and performs thereon necessary processing.

An acoustic space causing a long reverberation time allows collection of reflected and reverberant sounds of an impulse sound after some time passed from emission of the impulse sound. For this reason, reproduction of the accurate reverberation space requires a long time span of the impulse response waveform. In addition, reproducing such reverberation space needs to convolute a large amount of sampling data, thereby necessitating a vast amount of hardware resources. The conventional methods adopt relatively simple hardware configuration in a practical view as described below.

(Method 1)

Method of using only an initial part of sampling data of the impulse response waveform:

This method performs a convolution using data included in a specified period from the time of impulse sound emission to generate an acoustic signal for the initial reflection sound. A cyclic filter is used to artificially produce a late acoustic signal for the succeeding reverberant sound independently of the impulse response. The method connects the acoustic signal of the initial reflection sound with the artificial signal of the succeeding reverberant sound.

However, this method generates the artificial signal for the succeeding reverberant sound independently of the impulse response. There is a problem of audibly unnatural continuity between the initial reflection sound and the succeeding reverberant sound when these sounds are connected with each other. Natural continuity between the initial and subsequent signals requires complicated works such as fine adjustment of filter coefficients.

(Method 2)

Method of using only dominant or main values out of the entire sampling data of the impulse response waveform:

For example, the method samples an impulse response waveform at a specified sampling frequency to obtain data values. The method extracts data satisfying a specified level or higher from these data values and uses the extracted data as dominant or main data. The method performs a convolution operation using only the main data.

However, this method uses only the main data out of the entire sampling data of the impulse response waveform. That is to say, minor data other than the main or major data is screened out, thereby seriously excluding acoustic characteristics of the space. As a result, there is the problem that the acoustic space cannot be reproduced satisfactorily.

### SUMMARY OF THE INVENTION

The present invention has been made in consideration of the foregoing. It is therefore an object of the present invention to provide a reverberation generating apparatus and a method of generating a reverberation effect capable of representing a sufficient sound field on the basis of a simple configuration.

In order to solve the above-mentioned problems, a reverberation generating apparatus according to the present invention is designed for applying a reverberation effect to an acoustic signal for output based on sampling data representative of an impulse response waveform. The inventive apparatus comprises a first operating section that processes the acoustic signal with sampling data corresponding to an initial period of the impulse response waveform so as to generate an initial acoustic signal, the initial period of the impulse response waveform being determined from a point of impulse sound emission to a point after a lapse of a specified time, a second operating section that processes the acoustic signal with sampling data corresponding to a selected period of the impulse response waveform so as to generate an additional acoustic signal, an attenuation operating section that recurrently outputs the additional acoustic signal while attenuating the additional acoustic signal so as to generate a late acoustic signal, and an output section that synthesizes the initial acoustic signal and the late acoustic signal for the output. Preferably, the output section synthesizes the initial acoustic signal and the late acoustic signal with a delay therebetween such that the initial acoustic signal smoothly connects to the late acoustic signal. Preferably, the second operating section convolutes the acoustic signal with the sampling data corresponding to the selected period of the impulse response waveform, which is selected subsequently to the initial period from the same impulse response waveform.

The reverberation generating apparatus having this configuration convolutes sampling data of an impulse response waveform by the first operating section, more specifically, such sampling data corresponding to an initial period after a lapse of specified time from the time of impulse sound emission. In this manner, the apparatus can generate an initial acoustic signal, mainly a signal related to the initial reflection sound by means of the first operating section. Accordingly, it is possible to faithfully reproduce an impulse response for data concerning the initial reflection sound that characterizes an acoustic space.

Further, sampling data of the impulse response waveform corresponding to a specified period is utilized such that the apparatus can convolute that data by means of the second operating section to generate an additional acoustic signal. Then, the apparatus can generate a late acoustic signal mainly representative of a late reflected sound by repeatedly attenuating the additional acoustic signal by means of the attenuation operating section. Therefore, this eliminates the need to convolute all sampling data of the impulse response waveform, enabling a simple configuration without the need for a large amount of hardware resources. The initial acoustic signal and the late acoustic signal are generated on the basis of sampling data extracted from the same impulse response waveform. When the initial acoustic signal is synthesized with the late acoustic signal by means of the output section, unnatural continuity of the initial and subsequent signals can be avoided. That is to say, it is possible to represent a sufficient sound field effect through the use of a simple configuration and small computation amount, that is the bi-stage convolution of the sampling data.

Another inventive apparatus is designed for applying a reverberation effect to an acoustic signal for output based on sampling data representative of an impulse response waveform. The inventive apparatus comprises a first operating section that processes the acoustic signal with sampling data corresponding to an initial period of the impulse response waveform so as to generate an initial acoustic signal, the initial period of the impulse response waveform being determined from a point of impulse sound emission to a point after a lapse of a specified time, a second operating section that processes the acoustic signal with sampling data corresponding to a selected period of the impulse response waveform so as to generate an additional acoustic signal, an attenuation operating section that recurrently outputs the additional acoustic signal while attenuating the additional acoustic signal so as to generate an attenuating acoustic signal with a certain density and a phase, a diffusing section that adjusts either of the density and the phase of the attenuating acoustic signal so as to generate a late acoustic signal, and an output section that synthesizes the initial acoustic signal and the late acoustic signal for the output.

A further inventive apparatus is likewise designed for applying a reverberation effect to an acoustic signal for output based on sampling data representative of an impulse response waveform, and comprises a operating section that processes the acoustic signal with sampling data corresponding to an initial period of the impulse response waveform so as to generate an initial acoustic signal, the initial period of the impulse response waveform being determined from a point of impulse sound emission to a point after a lapse of a specified time, an attenuation operating section that recurrently outputs the initial acoustic signal while attenuating the initial acoustic signal so as to generate a late acoustic signal and an output section that synthesizes the initial acoustic signal and the late acoustic signal for the output.

In order to solve the above-mentioned problems, another reverberation generating apparatus is designed according to the present invention. The inventive apparatus applies a reverberation effect to an acoustic signal for output based on sampling data representative of an impulse response waveform, and comprises a first operating section that processes the acoustic signal with sampling data corresponding to an initial period of the impulse response waveform so as to generate an initial acoustic signal, the initial period of the impulse response waveform being determined between a point of impulse sound emission and a first point after a lapse of a specified time, a second operating section that processes the acoustic signal with sampling data corresponding to a subsequent period of the impulse response waveform so as to generate a late acoustic signal, the subsequent period of the impulse response waveform being determined between the first point and a second point after a lapse of another specified time, an attenuation operating section that recurrently outputs the late acoustic signal while attenuating the late acoustic signal so as to generate a reverberation signal, and an output section that synthesizes the initial acoustic signal, the late acoustic signal and the reverberation signal for the output. Preferably, the inventive apparatus further comprises a storage section that stores the sampling data corresponding to the initial period of the impulse response waveform for feeding the first convoluting operation section and the sampling data corresponding to the subsequent period of the same impulse response waveform for feeding the second convoluting operation section. Preferably, the output section synthesizes the initial acoustic signal and the late acoustic signal with a delay therebetween such that the initial acoustic signal smoothly connects to the late acoustic signal.

The reverberation generating apparatus having this configuration convolutes sampling data of an impulse response waveform by means of the first operating section, more specifically, such sampling data corresponding to an initial period after a lapse of first specified time from the time of impulse sound emission. In this manner, the apparatus can generate an initial acoustic signal, mainly a signal related to the initial reflection sound, by means of the first operating section. Further, it is possible to generate a late acoustic signal (a signal subsequent to the initial reflection sound) by convoluting sampling data of the impulse response waveform, more specifically, such sampling data corresponding to a subsequent period after a lapse of the initial period, by means of the second operating section. Accordingly, it is possible to faithfully reproduce an impulse response concerning a relatively initial stage that characterizes an acoustic space by means of the bi-stage convolution.

In addition, it is possible to generate a reverberation signal (a signal related to reverberant sound) by repeatedly attenuating the signal obtained by convolution processing in the second operating section. Therefore, this eliminates the need to convolute all sampling data of the impulse response waveform, enabling a simple configuration without the need for a large amount of hardware resources. The initial acoustic signal, the late acoustic signal, and the reverberation signal are generated on the basis of the same impulse response waveform. When the initial acoustic signal, the late acoustic signal, and the reverberation signal are synthesized by means of the output section, unnatural continuity of signals can be avoided. That is to say, it is possible to represent a sufficient sound field effect through the use of a simple configuration.

Another inventive apparatus is designed for applying a reverberation effect to an acoustic signal for output based on sampling data representative of an impulse response waveform, and comprises a first operating section, a second operating section, an attenuation operating section, a diffusing section, and an output section. The first operating section convolutes the acoustic signal with sampling data corresponding to an initial period of the impulse response waveform so as to generate an initial acoustic signal. The initial period of the impulse response waveform is determined between a point of impulse sound emission and a first point after a lapse of a specified time. The second operating section convolutes the acoustic signal with sampling data corresponding to a subsequent period of the impulse response waveform so as to generate a late acoustic signal. The subsequent period of the impulse response waveform is determined between the first point and a second point after a lapse of another specified time. The attenuation operating section recurrently outputs the late acoustic signal while attenuating the late acoustic signal so as to generate an attenuating acoustic signal with a certain density and a phase. The diffusing section adjusts either of the density and the phase of the attenuating acoustic signal so as to generate a reverberation signal. The output section synthesizes the initial acoustic signal, the late acoustic signal and the reverberation signal for the output.

An inventive method is designed for applying a reverberation effect to an acoustic signal for output based on sampling data representative of an impulse response waveform. The inventive method comprises a first operating step of processing the acoustic signal with sampling data corresponding to an initial period of the impulse response waveform so as to generate an initial acoustic signal, the initial period of the impulse response waveform being determined from a point of impulse sound emission to a point after a lapse of a specified time, a second operating step of processing the acoustic signal with sampling data corresponding to a selected period of the impulse response waveform so as to generate an additional acoustic signal, an attenuation operating step of recurrently outputting the additional acoustic signal while attenuating the additional acoustic signal so as to generate a late acoustic signal, and an output step of synthesizing the initial acoustic signal and the late acoustic signal for the output.

Alternatively, the inventive method comprises a first operating step of processing the acoustic signal with sampling data corresponding to an initial period of the impulse response waveform so as to generate an initial acoustic signal, the initial period of the impulse response waveform being determined from a point of impulse sound emission to a point after a lapse of a specified time, a second operating step of processing the acoustic signal with sampling data corresponding to a selected period of the impulse response waveform so as to generate an additional acoustic signal, an attenuation operating step of recurrently outputting the additional acoustic signal while attenuating the additional acoustic signal so as to generate an attenuating acoustic signal with a certain density and a phase, a diffusing step of adjusting either of the density and the phase of the attenuating acoustic signal so as to generate a late acoustic signal, and an output step of synthesizing the initial acoustic signal and the late acoustic signal for the output.

Alternatively, the inventive method may comprise a first operating step of processing the acoustic signal with sampling data corresponding to an initial period of the impulse response waveform so as to generate an initial acoustic signal, the initial period of the impulse response waveform being determined between a point of impulse sound emission and a first point after a lapse of a specified time, a second operating step of processing the acoustic signal with sampling data corresponding to a subsequent period of the impulse response waveform so as to generate a late acoustic signal, the subsequent period of the impulse response waveform being determined between the first point and a second point after a lapse of another specified time, an attenuation operating step of recurrently outputting the late acoustic signal while attenuating the late acoustic signal so as to generate a reverberation signal, and an output step of synthesizing the initial acoustic signal, the late acoustic signal and the reverberation signal for the output.

Otherwise, the inventive method comprises a first operating step of processing the acoustic signal with sampling data corresponding to an initial period of the impulse response waveform so as to generate an initial acoustic signal, the initial period of the impulse response waveform being determined between a point of impulse sound emission and a first point after a lapse of a specified time, a second operating step of processing the acoustic signal with sampling data corresponding to a subsequent period of the impulse response waveform so as to generate a late acoustic signal, the subsequent period of the impulse response waveform being determined between the first point and a second point after a lapse of another specified time, an attenuation operating step of recurrently outputting the late acoustic signal while attenuating the late acoustic signal so as to generate an attenuating acoustic signal with a certain density and a phase, a diffusing step of adjusting either of the density and the phase of the attenuating acoustic signal so as to generate a reverberation signal, and an output step of synthesizing the initial acoustic signal, the late acoustic signal and the reverberation signal for the output.

The invention includes a program for use in an apparatus having a CPU and applying a reverberation effect to an acoustic signal for output based on sampling data representative of an impulse response waveform. The program may be stored in a computer-readable medium such as a hard disk, CD, and ROM. The inventive program is executable by the CPU for causing the apparatus to perform a method comprising a first operating step of processing the acoustic signal with sampling data corresponding to an initial period of the impulse response waveform so as to generate an initial acoustic signal, the initial period of the impulse response waveform being determined from a point of impulse sound emission to a point after a lapse of a specified time, a second operating step of processing the acoustic signal with sampling data corresponding to a selected period of the impulse response waveform so as to generate an additional acoustic signal, an attenuation operating step of recurrently outputting the additional acoustic signal while attenuating the additional acoustic signal so as to generate a late acoustic signal, and an output step of synthesizing the initial acoustic signal and the late acoustic signal for the output.

Alternatively, the inventive program is executable by the CPU for causing the apparatus to perform a method comprising a first operating step of processing the acoustic signal with sampling data corresponding to an initial period of the impulse response waveform so as to generate an initial acoustic signal, the initial period of the impulse response waveform being determined from a point of impulse sound emission to a point after a lapse of a specified time, a second operating step of processing the acoustic signal with sampling data corresponding to a selected period of the impulse response waveform so as to generate an additional acoustic signal, an attenuation operating step of recurrently outputting the additional acoustic signal while attenuating the additional acoustic signal so as to generate an attenuating acoustic signal with a certain density and a phase, a diffusing step of adjusting either of the density and the phase of the attenuating acoustic signal so as to generate a late acoustic signal, and an output step of synthesizing the initial acoustic signal and the late acoustic signal for the output.

Alternatively, the inventive program is executable by the CPU for causing the apparatus to perform a method comprising a first operating step of processing the acoustic signal with sampling data corresponding to an initial period of the impulse response waveform so as to generate an initial acoustic signal, the initial period of the impulse response waveform being determined between a point of impulse sound emission and a first point after a lapse of a specified time, a second operating step of processing the acoustic signal with sampling data corresponding to a subsequent period of the impulse response waveform so as to generate a late acoustic signal, the subsequent period of the impulse response waveform being determined between the first point and a second point after a lapse of another specified time, an attenuation operating step of recurrently outputting the late acoustic signal while attenuating the late acoustic signal so as to generate a reverberation signal, and an output step of synthesizing the initial acoustic signal, the late acoustic signal and the reverberation signal for the output.

Otherwise, the inventive program is executable by the CPU for causing the apparatus to perform a method comprising a first operating step of processing the acoustic signal with sampling data corresponding to an initial period of the impulse response waveform so as to generate an initial acoustic signal, the initial period of the impulse response waveform being determined between a point of impulse sound emission and a first point after a lapse of a specified time, a second operating step of processing the acoustic signal with sampling data corresponding to a subsequent period of the impulse response waveform so as to generate a late acoustic signal, the subsequent period of the impulse response waveform being determined between the first point and a second point after a lapse of another specified time, an attenuation operating step of recurrently outputting the late acoustic signal while attenuating the late acoustic signal so as to generate an attenuating acoustic signal with a certain density and a phase, a diffusing step of adjusting either of the density and the phase of the attenuating acoustic signal so as to generate a reverberation signal, and an output step of synthesizing the initial acoustic signal, the late acoustic signal and the reverberation signal for the output.

### BRIEF DESCRIPTION OF THE DRAWINGS

FIG. 1 is a configuration diagram of the effector 100 according to a first embodiment of the present invention.

FIG. 2 schematically shows sampling data of a impulse response waveform for the first embodiment.

FIG. 3 schematically shows contents of data in the reverberation data memory 107 of the effector 100 according to the first embodiment of the present invention.

FIG. 4 is a configuration diagram of the reverberation generating section 120 in the effector 100.

FIG. 5 is a configuration diagram of the first convolution operating section 121 in the effector 100.

FIG. 6 is a configuration diagram of the second convolution operating section 122 in the effector 100.

FIG. 7 explains contents of signal processing of the filter 125 in the effector 100.

FIG. 8 explains contents of signal processing of the filter 125 in the effector 100.

FIG. 9 explains contents of signal processing of the reverberation generating section 120 in the effector 100.

FIG. 10 is a configuration diagram of an effector according to a second modification of the first embodiment of the present invention.

FIG. 11 is a configuration diagram of an effector according to a third modification of the first embodiment of the present invention.

FIG. 12 is a configuration example of the density adjustment filter 126 in the effector according to the third modification of the first embodiment of the present invention.

FIG. 13 explains contents of signal processing of the density adjustment filter 126.

FIG. 14 shows another configuration example of the density adjustment filter 126.

FIG. 15 shows still another configuration example of the density adjustment filter 126.

FIG. 16 explains contents of signal processing of the density adjustment filter 126.

FIG. 17 shows yet another configuration example of the density adjustment filter 126.

FIG. 18 shows still another configuration example of the density adjustment filter 126.

FIG. 19 shows still yet another configuration example of the density adjustment filter 126.

FIG. 20 explains a sixth modification of the first embodiment of the present invention.

FIG. 21 schematically shows sampling data of a impulse response waveform for use in a second embodiment of the invention.

FIG. 22 is a configuration diagram of the reverberation generating section 120 in the effector 100 of the second embodiment.

FIG. 23 explains contents of signal processing of the reverberation generating section 120 in the effector 100.

FIG. 24 is a configuration diagram of an effector according to a second modification of the second embodiment of the present invention.

### DETAILED DESCRIPTION OF THE INVENTION

Embodiments of the present invention will be described in further detail with reference to the accompanying drawings.

A: Configuration and Operation of a First Embodiment

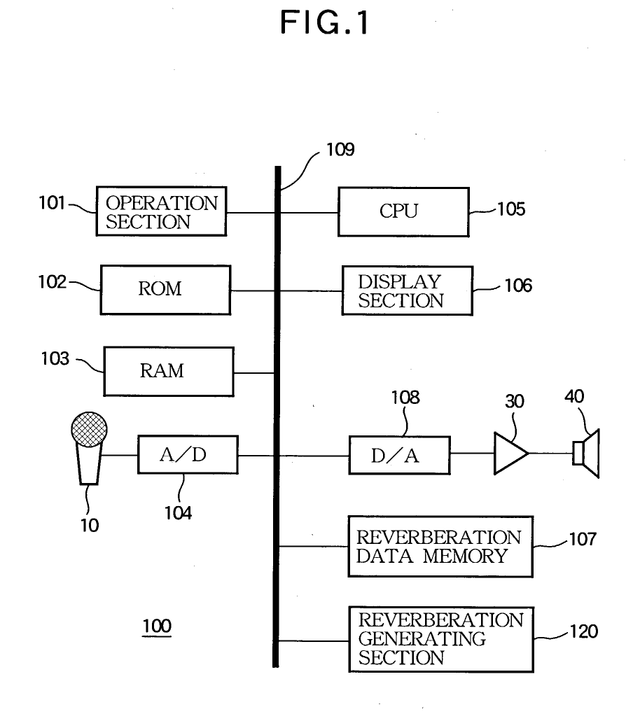

FIG. 1 is a block diagram exemplifying a configuration of an effector 100 as the first embodiment of the present invention.

The effector 100 stores: an impulse response waveform measured in an acoustic space such as a hall and a church; and impulse response waveform's sampling data obtained by simulation. The effector 100 applies a convolution operation to the sampling data with an acoustic signal and functions as a reverberation generating apparatus that generates a signal provided with the reverberation effect such as an initial reflection sound and a late reverberation sound for the acoustic space.

As shown in FIG. 1, the effector 100 comprises an operation section 101, ROM (Read Only Memory) 102, RAM (Random Access Memory) 103, A/D (Analog/Digital) conversion circuit 104, a CPU (Central Processing Unit) 105, a display section 106, reverberation data memory 107, a D/A (Digital/Analog) conversion circuit 108, and a reverberation generating section 120. These components are connected to each other via a bus 109.

A microphone 10 is connected to the A/D conversion circuit 104. A speaker 40 is connected to the D/A conversion circuit 108 via an amplifier 30.

When a user operates keys on an operation panel, the operation section 101 outputs an operation signal corresponding to the operation to the CPU 105.

The ROM 102 stores various programs for controlling each part of the effector 100. The RAM 103 is used as a working area and temporarily stores data needed for processing such as reverberation generation.

The A/D conversion circuit 104 samples and outputs an input signal each time the circuit is supplied with a sampling clock at a specified frequency.

The CPU 105 executes the programs stored in the ROM 102 to control the apparatus components connected via the bus 109.

The display section 106 comprises a liquid crystal display panel and a drive circuit for controlling display of the liquid crystal display panel.

The reverberation data memory 107 stores sampling data of an impulse response waveform.

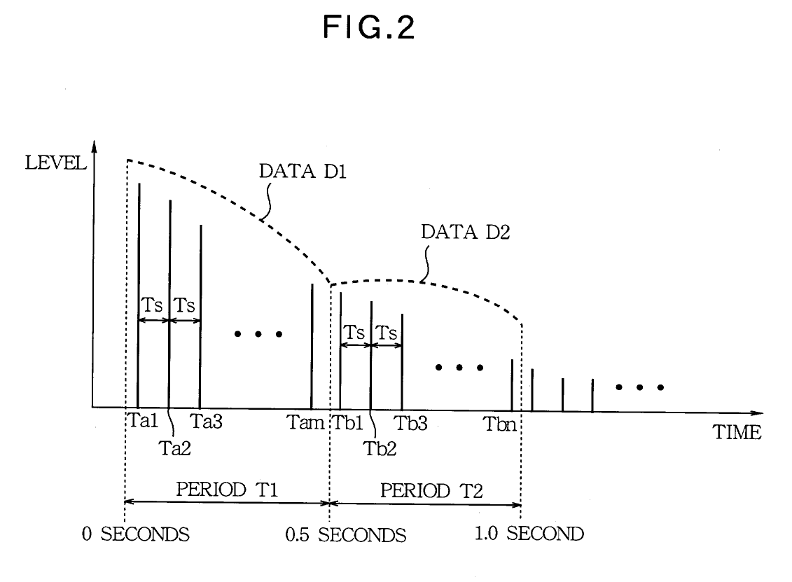

The reverberation data memory 107 of the effector 100 according to the present invention stores part of the sampling data, not all the sampling data for impulse response waveforms. FIG. 2 schematically shows the sampling data of an impulse response waveform. In FIG. 2, the abscissa indicates the time and the ordinate indicates the signal level. The example here shows sampling at sampling time Ts.

The sampling data of the impulse response waveform contains data D1 during initial period T1 from the time of impulse sound emission (0 seconds) to 0.5 seconds. The reverberation data memory 107 stores data D1 as “initial reflection sound data”. The reverberation data memory 107 stores data D2 as “late reverberation sound data” contained during period T2 from 0.5 to 1.0 second. The “initial reflection sound data” may be preceded by a period whose data value is almost 0. Data for such period may not be stored in the reverberation data memory 107. This saves the amount of memory used for the reverberation data memory 107.

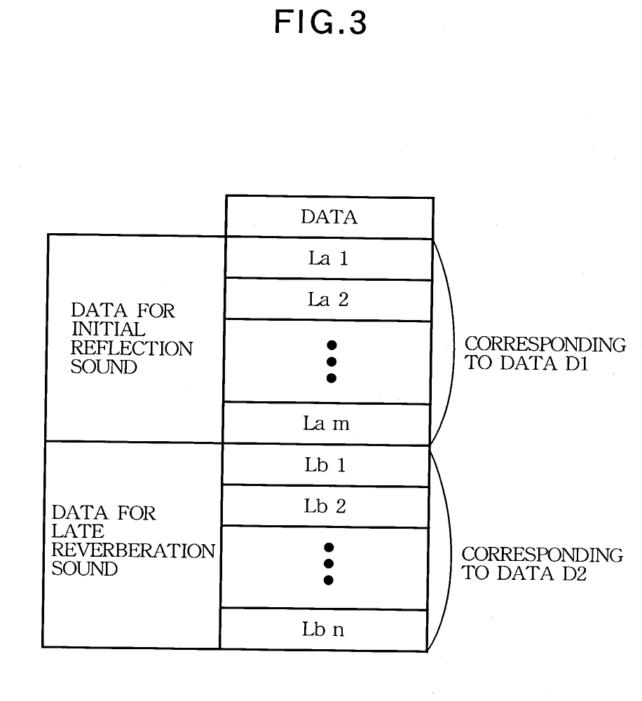

As shown in FIG. 3, the reverberation data memory 107 stores data values of the sampling data for the corresponding period as time-series data for each sampling time Ts. Information about the data values to be stored may be sampling data values for the impulse response waveform or values normalized at a given level of the sampling data of the impulse response waveform. The time information about each sample data may be stored correspondingly to the data value.

The reverberation generating section 120 has a function of generating data provided with a reverberation effect from sampling data of input signals such as acoustic signals.

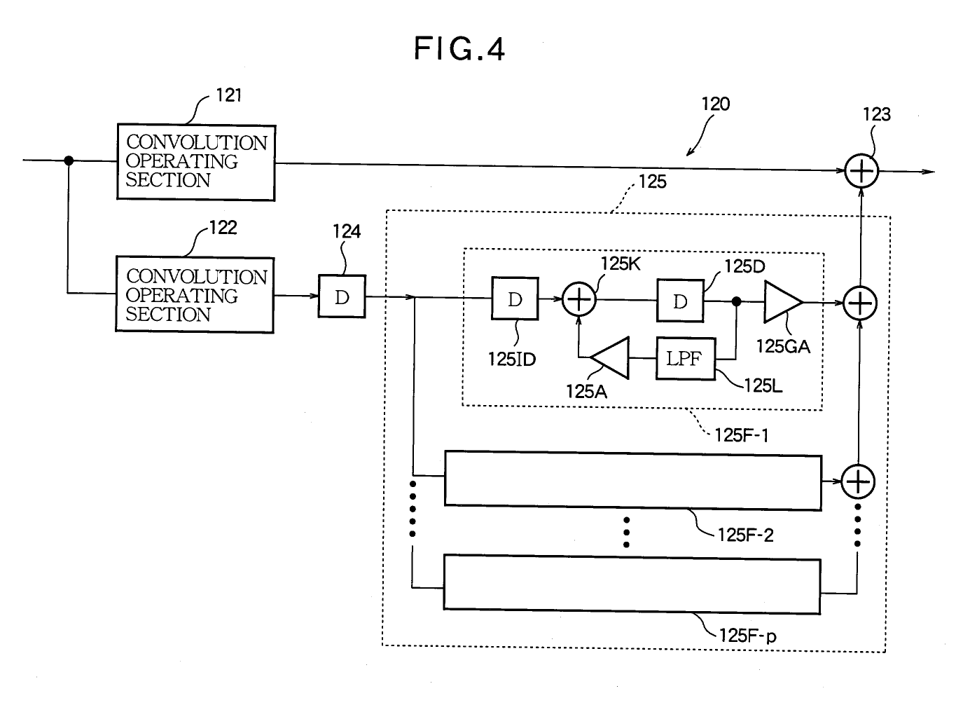

FIG. 4 is an internal block diagram of the reverberation generating section 120. The reverberation generating section 120 comprises a first convolution operating section 121, a second convolution operating section 122, an adder 123, a delay circuit 124, and a filter 125.

The first convolution operating section 121 convolutes sampling data of the acoustic signal with initial reflection sound data D1 stored in the reverberation data memory 107.

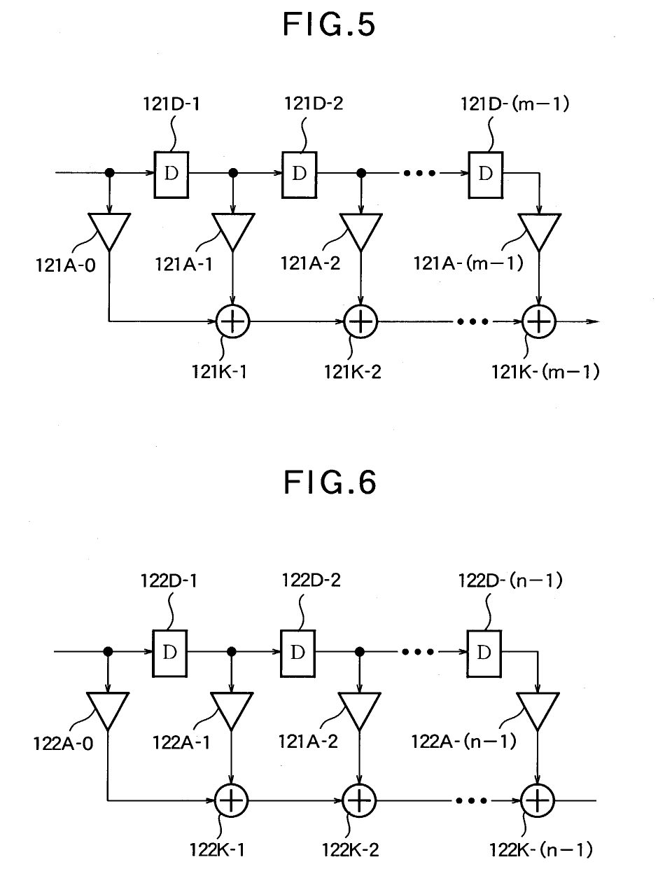

As shown in FIG. 5, the convolution operating section 121 comprises delay circuits 121D-1, 121D-2, . . . , and 121D-(m−1), multipliers 121A-0, 121A-1, 121A-2, . . . , and 121A-(m−1), and adders 121K-1, 121K-2, . . . , and 121K-(m−1). The convolution operating section 121 performs an m-stage convolution.

Delay time T121 for the delay circuits 121D-1, 121D2, . . . , and 121D-(m−1) corresponds to the sampling time Ts for the impulse response waveform. Initial reflection sound data D1 (La1, La2, . . . , and Lam) in the reverberation data memory 107 is used as multiplication coefficients for the multiplier 121A-0, 121A-1, 121A-2, . . . , and 121A-(m−1). More specifically, initial reflection sound data La1 is used as a multiplication coefficient for the multiplier 121A-0. Initial reflection sound data La2 is used as a multiplication coefficient for the multiplier 121A-1, and so on. Initial reflection sound data Lam is used as a multiplication coefficient for the multiplier 121A-(m−1).

The second convolution operating section 122 convolutes sampling data of the acoustic signal with late reverberation sound data D2 stored in the reverberation data memory 107.

As shown in FIG. 6, the second convolution operating section 122 comprises delay circuits 122D-1, 122D-2, . . . , and 122D-(n−1), multipliers 122A-0, 122A-1, 122A-2, . . . , and 122A-(n−1), and adders 122K-1, 122K-2, . . . , and 122K-(n−1). The convolution operating section 122 performs an n-stage convolution.

Delay time T122 for the delay circuits 122D-1, 122D2, . . . , and 122D-(n−1) corresponds to the sampling time Ts for the impulse response waveform. Late reverberation sound data D2 (Lb1, Lb2, . . . , and Lbn) in the reverberation data memory 107 is used as multiplication coefficients for the multiplier 122A-0, 122A-1, 122A-2, . . . , and 122A-(n−1). More specifically, late reverberation sound data Lb1 is used as a multiplication coefficient for the multiplier 122A-0. Late reverberation sound data Lb2 is used as a multiplication coefficient for the multiplier 122A-2, and so on. Late reverberation sound data Lan is used as a multiplication coefficient for the multiplier 122A-(n−1).

The delay circuit 124 delays data for specified time T124. The specified time T124 is adjusted so as to be equivalent to a time length of the initial reflection sound data to be convoluted in the convolution operating section 121. Namely, the output section synthesizes the initial acoustic signal and the late acoustic signal with a delay T124 therebetween such that the initial acoustic signal smoothly connects to the late acoustic signal.

The filter 125 has a feedback loop. The embodiment uses a comb filter as shown in FIG. 4 for the filter 125.

In more detail, the filter 125 is configured by parallel connecting P filters 125F-1, 125F-2, . . . , and 125F-p as shown in FIG. 4. Each filter comprises delay circuits 125D and 125ID, a low-pass filter 125L, amplifiers 125A and 125GA, and an adder 125K. The delay circuit 125ID functions as an initial delay to supply a specified delay for an input signal to the filter 125F-1. The amplifier 125GA provides overall level adjustment for output signals from the filter 125F-1.

The low-pass filter just needs to attenuate a high range. A shelving filter may be used for the low-pass filter.

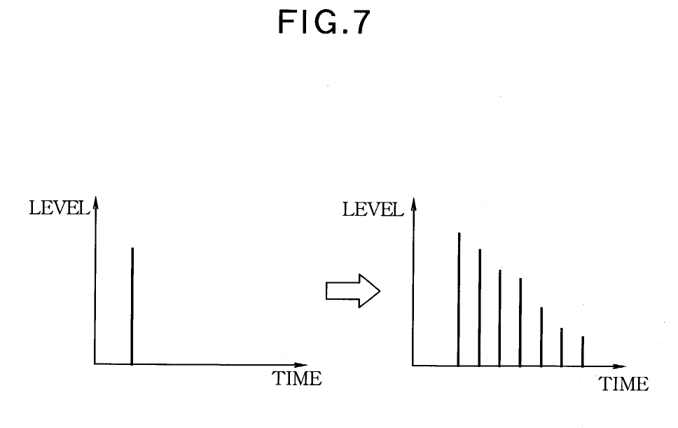

FIG. 7 shows an output signal when the filter 125F-1 is supplied with a pulse signal. As shown in FIG. 7, the output signal from the filter 125F-1 comprises successive data at an interval of delay time T125 controlled by the delay circuit 125D. When an amplification coefficient of the amplifier 125A is set to a value smaller than 1, the filter 125F-1 can output a signal having natural attenuation characteristics as shown in FIG. 7. Namely, the attenuation operating section composed of the filter 125 recurrently filters and outputs a pulse contained in the additional acoustic signal while attenuating the level of the additional acoustic signal so as to generate a late acoustic signal containing a train of attenuated pulses; and

The low-pass filter 125L constituting the filter 125F-1 can remove high-frequency signal components higher than or equal to a specified frequency. Therefore, by adjusting a filter coefficient of the low-pass filter constituting each of the filters 125F-1, 125F-2, . . . , and 125F-p and by adjusting an amplification coefficient of the amplifier 125GA to amplify and output signal from each filter, for example, it is possible to reproduce such acoustic characteristics in an actual acoustic space that a higher frequency signal provides a shorter reverberation time.

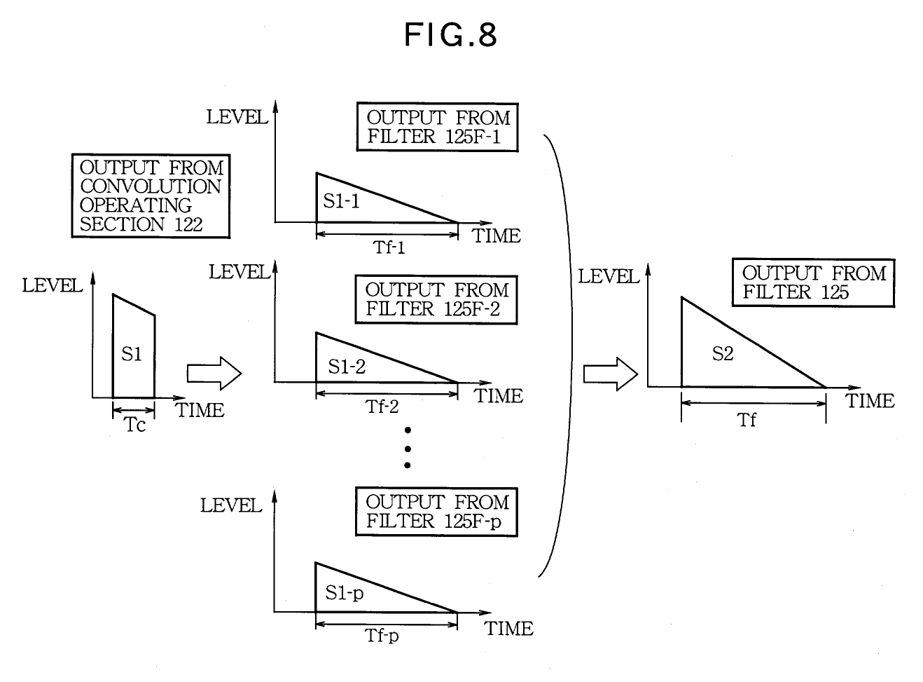

FIG. 8 schematically shows relationship among an output signal S1 from the convolution operating section 122, output signals S1-1, S1-2, . . . , and S1-p from the filters 125F-1, 125F-2, . . . , and 125F-p, respectively, and an output signal S2 from the filter 125.

The signal S1 is obtained from an operation result of the convolution operating section 122 and is supplied to the filters 125F-1, 125F-2, . . . , and 125F-p. Each filter outputs a signal component by repeatedly attenuating it. The signal component corresponds to the filter coefficient of that filter. The output signals S1-1, S1-2, . . . , and S1-p from the respective filters are synthesized to be the signal S2 which is then output from the filter 125.

That is to say, as shown in FIG. 8, the filter 125 can generate and output the attenuated signal S2 whose period Tf is longer than the period Tc (Tf>Tc) of the signal S1 obtained from the operation result of the convolution operating section 122.

For the sake of convenience, FIG. 8 uses the same signal form for the output signals S1-1, S1-2, . . . , and S1-p from the filters 125F-1, 125F-2, . . . , and 125F-p. Actually, however, the output signals S1-1, S1-2, . . . , and S1-p cause different signal forms (frequency or attenuation characteristics) due to filter coefficient values of the filters 125F-1, 125F-2, . . . , and 125F-p.

The adder 123 synthesizes (adds) two supplied signals for output. According to the embodiment, the adder 123 outputs a signal synthesized of a signal obtained from the convolution operating section 121 and a signal output from the filter 125. Namely, the output section composed of the adder 123 synthesizes the initial acoustic signal and the late acoustic signal for the output by connecting these signals in series.

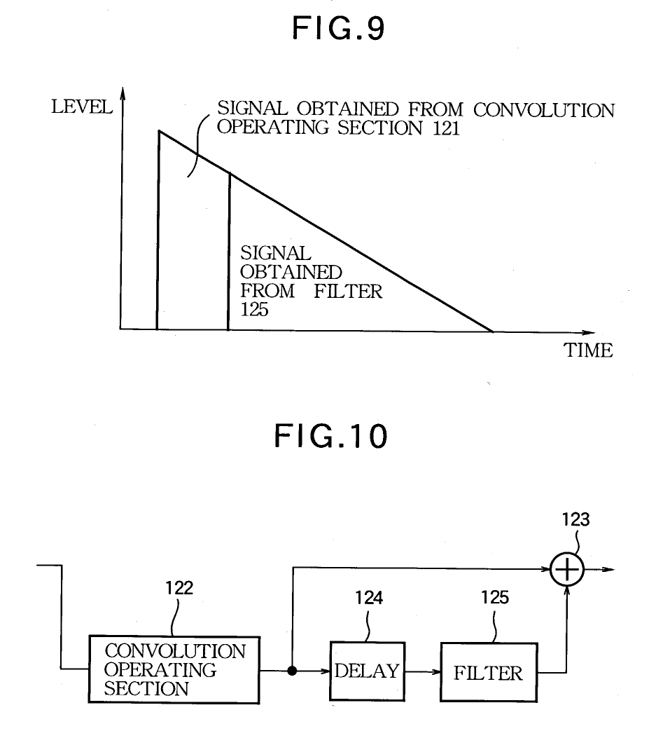

FIG. 9 schematically shows the output signal from the adder 123. According to the embodiment, as mentioned above, delay time T124 of the delay circuit 124 corresponds to a time length of the initial reflection sound data convoluted in the convolution operating section 121. During an impulse response in the reverberation generating section 120, the adder 123 first outputs a signal obtained from the convolution operating section 121, and then outputs a signal from the filter 125 (FIG. 9).

Multiplication coefficients used for the convolution operating sections 121 and 122 correspond to data based on the same impulse response waveform. The filter 125 adds reverberation characteristics to a signal obtained from the convolution operating section 122. Consequently, even when a signal obtained from the convolution operating section 121 is followed by a signal output from the filter, there is no problem of audibly unnatural continuity between data. As schematically shown in FIG. 9, it is possible to output a signal well-continued as data from the adder 123.

Thereafter, the signal (digital signal) output from the adder 123 is supplied to the D/A conversion circuit 108 under control of the CPU 105. The D/A conversion circuit 108 converts the signal into an analog signal which is then output from the speaker 40 via the amplifier 30. The signal is output as a sound provided with the reverberation effect.

The effector 100 according to the present invention uses the first convolution operating section 121 to convolute sampling data of the impulse response waveform to generate signals related to the initial reflection sound, wherein the sampling data corresponds to an initial period (e.g., 0 to 0.5 seconds) for a specified time passed after the impulse sound emission. With respect to the initial reflection sound characterizing an acoustic space, it is possible to faithfully represent data contents of the impulse response waveform and fully represent acoustic characteristics.

Further, the second convolution operating section 122 convolutes sampling data of the impulse response waveform corresponding to a specified subsequent period (e.g., 0.5 to 1 second) and repeatedly attenuates a resulting signal. This makes it possible to generate signals related to the late reverberation sound. Therefore, it is unnecessary to convolute all the sampling data of the impulse response waveform. Sufficient acoustic characteristics can be represented without the need for a large amount of hardware resources.

The generation of reverberation signals is not based on sampling data during the initial reflection sound period that well characterizes the acoustic space and contains a relatively large reflected sound interval, but based on sampling data during the succeeding late reverberation sound period that contains a smaller reflected sound interval. For this reason, it is possible to generate a reverberant sound more faithfully reproducing acoustic characteristics of the impulse response wave.

Further, a signal related to the initial reflection sound and a signal related to the late reverberation sound are generated based on sampling data of the same impulse response waveform. When the adder 123 synthesizes both signals, there is no problem of an unnaturally connected signal. That is to say, it is possible to generate a signal provided with characteristics of the original reverberation space from an input signal.

Since the filter 125 can properly control the contents of reverberation characteristics to be provided, it is possible to freely control the reverberation time by maintaining data contents of the impulse response waveform, in other words, maintaining the acoustic space characteristics.

B: Modifications

There has been described the first embodiment of the present invention. The embodiment is just an example. The present invention may be embodied in various modifications without departing from the spirit and scope of the invention. Available modifications are presented below.

(Modification 1)

The effector 100 according to the first embodiment classifies sampling data of the impulse response waveform into the “initial reflection sound data” contained in a period from the impulse sound emission (0 seconds) to 0.5 seconds and the “late reverberation sound data” contained in a period from 0.5 seconds to 1 second. These types of data are stored independently. This configuration can be changed in any form.

For example, the “initial reflection sound data” may be contained in a period from 0 to 0.3 seconds. The “late reverberation sound data” may be contained in a period from 0.5 to 1.0 second. In this manner, the “initial reflection sound data” and the “late reverberation sound data” may not be continuous.

Alternatively, the “initial reflection sound data” may be contained in a period from 0 to 0.5 seconds. The “late reverberation sound data” may be contained in a period from 0.3 to 0.7 seconds. In this manner, the “initial reflection sound data” and the “late reverberation sound data” may overlap with each other.

In any case, like the above-mentioned embodiment, it is unnecessary to convolute all the sampling data of the impulse response waveform. There is no problem of the need for a large amount of hardware resources. In addition, the “initial reflection sound data” and the “late reverberation sound data” are generated by using sampling data obtained from the same impulse response waveform. There is no problem of audibly unnatural continuity between data.

(Modification 2)

The “initial reflection sound data” and the “late reverberation sound data” may be completely the same. For example, of the sampling data of the impulse response waveform, data contained in a period from 0 to 0.5 seconds may be used as the “initial reflection sound data” and the “late reverberation sound data”

This is advantageous to be able to more simply configure the reverberation generating section 120 of the effector 100 as shown in FIG. 10.

According to the modification, the convolution operating section 122 convolutes data contained in a period from 1 to 0.5 seconds out of sampling data of the impulse response waveform. As a result, a signal related to the initial reflection sound is generated. When a signal is obtained from the operation result of the convolution operating section 122, the signal passes through the delay circuit 124. The filter 125 repeatedly attenuates that signal for output. That is to say, the filter 125 can generate a signal related to the late reverberation sound based on the operation result of the convolution operating section 122.

Like the above-mentioned embodiment, the modification can also represent a sufficient sound field effect using a simple configuration.

(Modification 3)

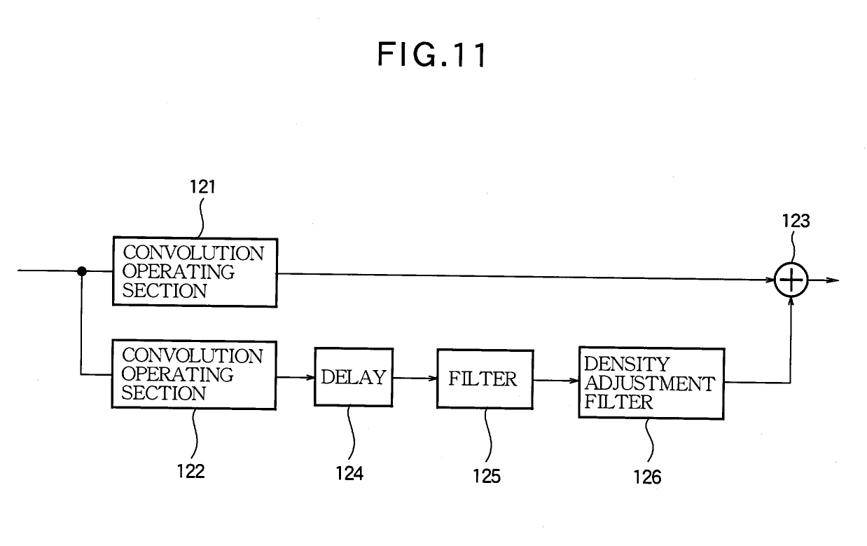

As shown in FIG. 11, the effector may be configured to include a density adjustment filter 126 after the filter 125. The density adjustment filter 126 is used for adjusting (diffusing) data densities (namely, densities of pulses contained in the acoustic signal) in the time axis direction and data phases (namely, phases of pulses contained in the acoustic signal).

Here, the purpose of diffusing the data density in the time axis direction takes the following into consideration. Generally, sampling data of the impulse response waveform enters a so-called diffusion area after a sufficient time passes from the point of impulse sound emission. This shortens a time interval to generate data (pulse signal).

Let us assume data phases for the impulse response waveform to be a left-right balance of the human acoustic sense. Then, the purpose of diffusing data phases is to reproduce such acoustic characteristics that data phases show no distinctions after lapse of a sufficient time.

Diffusing data densities and phases makes it possible to simulate the late area (diffusion area) for impulse response in an acoustic space. Namely, the diffusing section adjusts either of the density and the phase of the pulse components contained in the attenuating acoustic signal in a diffusing manner so as to generate a late acoustic signal.

The following shows several specific configuration examples of the density adjustment filter 126.

(1) Configuration of Serially or Parallel Connecting All-Pass Filters (APFs)

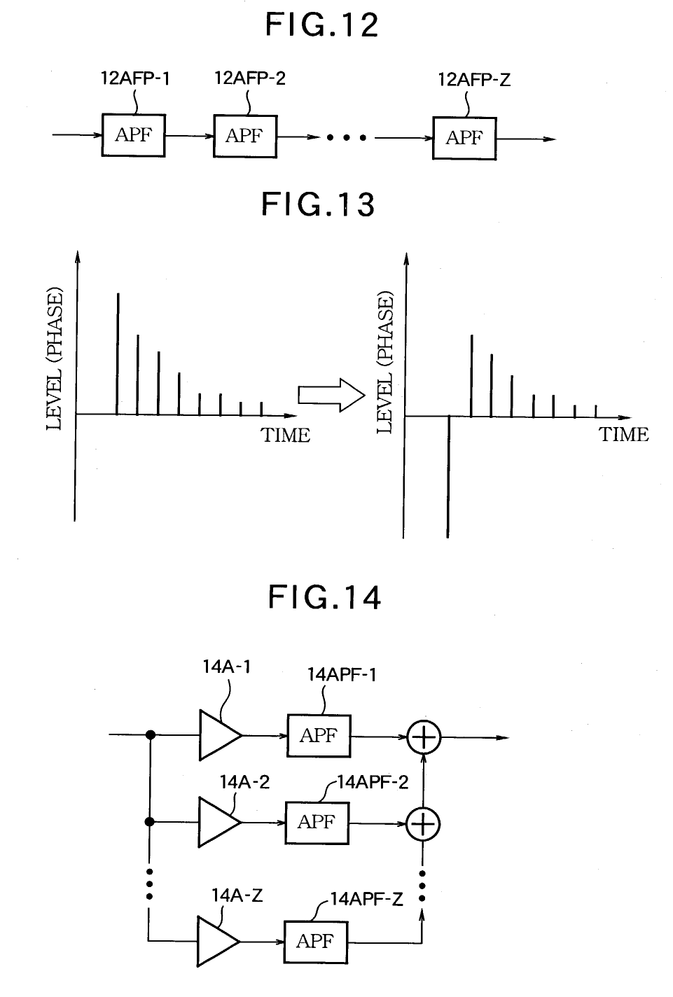

FIG. 12 shows a configuration of serially connecting as many as Z all-pass filters 12APF such as 12APF-1, 12APF-2, . . . , and 12APF-Z.

FIG. 13 exemplifies input and output waveforms for the all-pass filter 12APF. As shown in FIG. 13, the all-pass filter 12APF has a function of reversing the phase of the first signal. It is possible to generate and output signals with successively diffused phases by serially connecting all-pass filters 12APF-1, 2, . . . , and Z.

As shown in FIG. 14, the density adjustment filter 126 may be configured by parallel connecting as many as Z all-pass filters 14APF and multipliers 14A. Also in this case, it is possible to generate signals with diffused phases in response to an input signal.

(2) Configuration of Using All-Pass Filters (APFs) and Forming a Feedback Loop

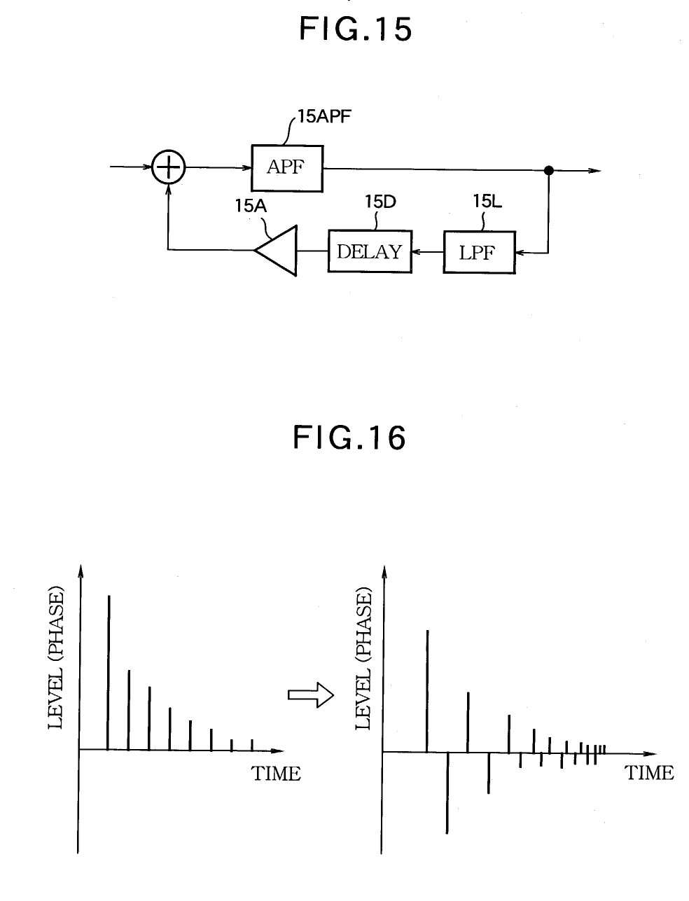

FIG. 15 shows a configuration that feeds back an output from the all-pass filter 15APF via a low-pass filter 15L, a delay circuit 15D, and a amplifier 15A.

FIG. 16 exemplifies input and output waveforms for the all-pass filter 15APF. The all-pass filter 15APF can diffuse phases of an input signal. Further, addition of a feedback signal makes it possible to gradually increase time densities of data.

Here, a gradual increase in time densities of data signifies gradual shortening of intervals for existence of data (pulse signal) in the time axis direction. Gradually increasing time densities of data can provide an effect that the human acoustic sense cannot distinguish pulses equivalent to individual reflected sounds. This makes it possible to reproduce a so-called diffusion area in the reverberation space.

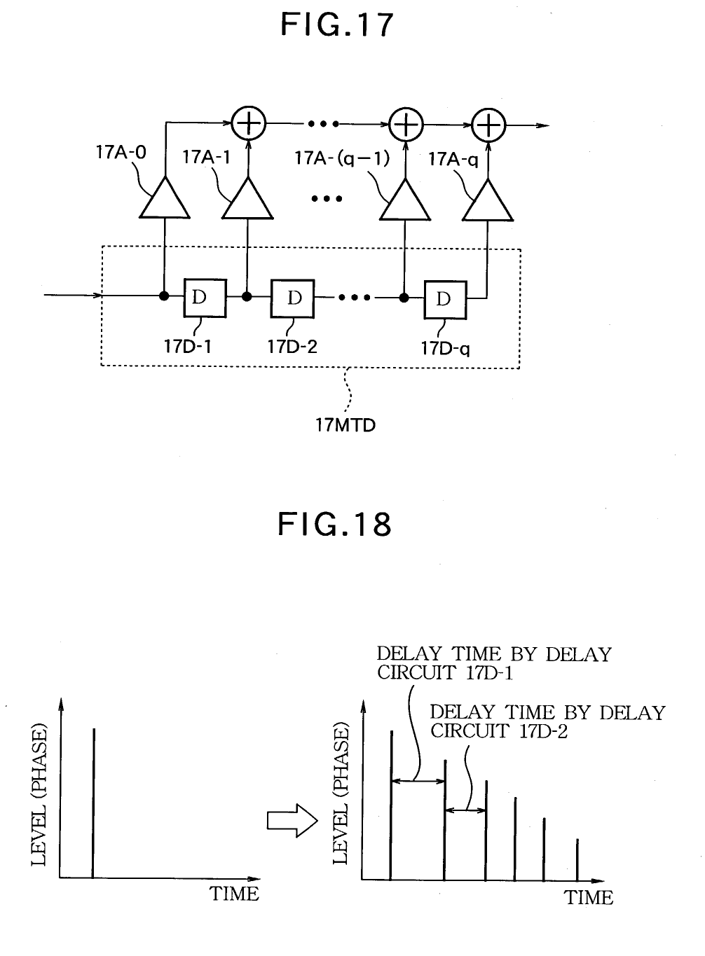

(3) Configuration of Using a Multitap Delay (FIG. 17)

FIG. 18 exemplifies input and output waveforms for a multitap delay 17MTD. Time densities of data can be gradually increased by adjusting delay times so that the delay times are differently adjusted for delay circuits 17D-1, 2, . . . , and q constituting the multitap delay 17MTD.

Moreover, data phases can be diffused by setting multiplication coefficients for multipliers 17A-0, 17A-1, 17A-q to the range of −1 to 1.

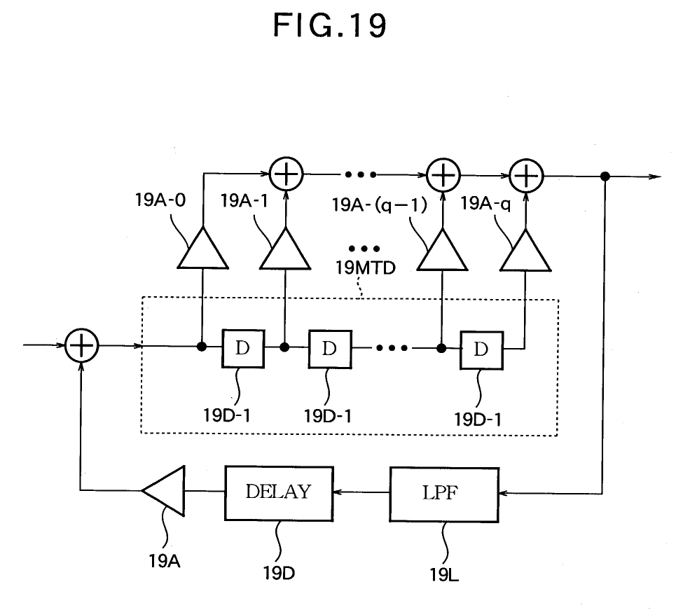

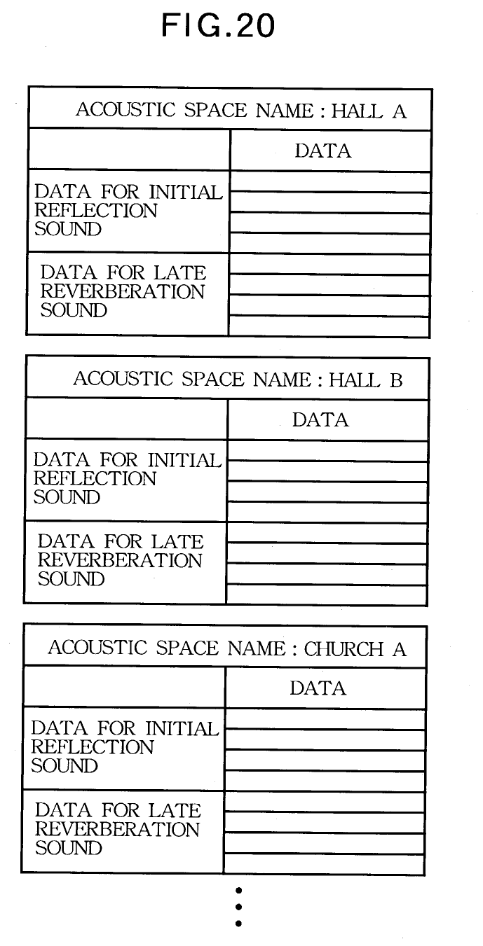

A configuration of forming a feedback loop (FIG. 19) can also increase time densities of data and diffuse data phases.

While there have been shown the specific configuration examples of the density adjustment filter 126, the density adjustment filter 126 may be configured by selecting one of these examples or combining some of them.

(Modification 4)

The above-mentioned first embodiment actually measures sampling data of the impulse response waveform. Further, it may be preferable to store a sound field simulation program in the ROM 102 and use a user-simulated impulse response waveform for any acoustic space as sampling data to be convoluted.

(Modification 5)

The present invention may be configured so that a user can specify a range of data areas to be used as “initial reflection sound data” and “late reverberation sound data” out of sampling data of the impulse response waveform. This configuration enables selection of data that better represents reverberation characteristics of the acoustic space.

(Modification 6)

The present invention may be configured to store a plurality of impulse response waveform data in the reverberation data memory 107. According to this configuration, the reverberation data memory 107 stores data associated with names of acoustic spaces such as halls and churches corresponding to respective impulse responses. The configuration may allow selection of an intended acoustic space in accordance with a user operation of the operation section 101.

(Modification 7)

While the above-mentioned embodiment describes the effector 100 provided with a reverberation generating function, it is obvious that the present invention is applicable to apparatuses such as mixers and reverbs provided with the reverberation generating function.

(Modification 8)

It is possible to use any recording media that store programs for the present invention. For example, available recording media include semiconductor memory, optical disks such as CD-ROM (Compact Disc-Read Only Memory) and CD-R(CompactDisc-Recordable), magneto-optical disks such as MO (Magneto Optical Disk) and MD (Mini Disc), and magnetic disks such as floppy disks and hard disks.

Any method can be used to install such programs. The above-mentioned recording media may be used to install the programs on the effector 100. Furthermore, a so-called online distribution method may be used to install programs related to the present invention on the effector 100 from a server storing the programs via networks such as the Internet.

A second embodiment of the invention will be described hereafter. The second embodiment has the same hardware construction as the first embodiment shown in FIG. 1. The difference is that the reverberation data memory 107 stores sampling data of the impulse response waveform adapted to the second embodiment.

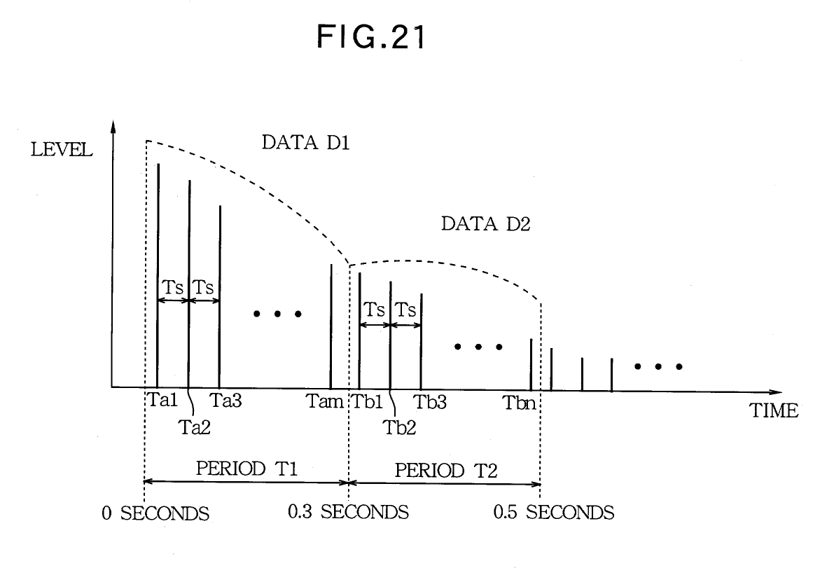

The reverberation data memory 107 of the effector 100 according to the second embodiment of the present invention stores only part of the sampling data for impulse response waveforms. FIG. 21 schematically shows the sampling data of an impulse response waveform adapted to the second embodiment. In FIG. 21, the abscissa indicates the time and the ordinate indicates the signal level. The sampling time is Ts.

The sampling data of the impulse response waveform contains data D1 during specified period T1 (e.g., 0.3 seconds from the time of impulse sound emission). The reverberation data memory 107 stores data D1 as “initial reflection sound data”. Data D2 is contained during specified period T2 (e.g., 0.3 to 0.5 seconds with reference to the time of impulse sound emission) following the specified period T1. The reverberation data memory 107 stores data D2 as “late reverberation sound data”. Here, the periods T1 and T2 are chronologically continuous. The “initial reflection sound data” may be preceded by a period whose data value is almost 0. Data for such period may not be stored in the reverberation data memory 107. This saves the amount of memory used for the reverberation data memory 107.

As mentioned before in conjunction with FIG. 3, the reverberation data memory 107 stores data values of the sampling data for the corresponding period as time-series data for each sampling time Ts. Information about the data values to be stored may be sampling data values for the impulse response waveform or values normalized at a given level of the sampling data of the impulse response waveform. The time information about each sample data may be stored correspondingly to the data value.

The reverberation generating section 120 has a function of generating data provided with a reverberation effect from sampling data of input signals such as acoustic signals.

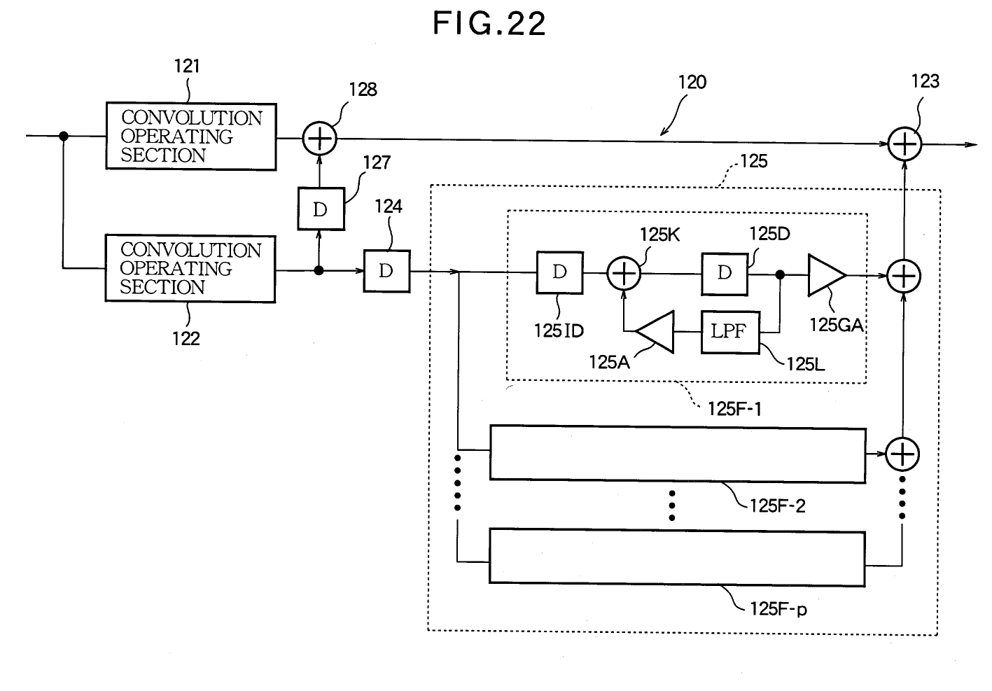

FIG. 22 is an internal block diagram of the reverberation generating section 120 of the second embodiment. The reverberation generating section 120 comprises a first convolution operating section 121, a second convolution operating section 122, an adder 123, a delay circuit 124, a filter 125, a delay circuit 127, and an adder 128.

The first convolution operating section 121 convolutes sampling data of the acoustic signal with initial reflection sound data D1 stored in the reverberation data memory 107 and outputs an operation result to the adder 128.

As mentioned before in conjunction with FIG. 5, the first convolution operating section 121 comprises delay circuits 121D-1, 121D-2, . . . , and 121D-(m−1), multipliers 121A-0, 121A-1, 121A-2, . . . and 121A-(m−1), and adders 121K1, 121K-2, . . . , and 121K-(m−1). The convolution operating section 121 performs an m-stage convolution.

Delay time T121 for the delay circuits 121D-1, 121D2, . . . , and 121D-(m−1) corresponds to the sampling time Ts for the impulse response waveform. Initial reflection sound data D1 (La1, La2, . . . , and Lam) in the reverberation data memory 107 is used as multiplication coefficients for the multiplier 121A-0, 121A-1, 121A-2, . . . , and 121A-(m−1). More specifically, initial reflection sound data La1 is used as a multiplication coefficient for the multiplier 121A-0. Initial reflection sound data La2 is used as a multiplication coefficient for the multiplier 121A-1, and so on. Initial reflection sound data Lam is used as a multiplication coefficient for the multiplier 121A-(m−1).

The second convolution operating section 122 convolutes sampling data of the acoustic signal with late reverberation sound data D2 stored in the reverberation data memory 107 and outputs an operation result to the delay circuits 124 and 127.

As mentioned before in conjunction with FIG. 6, the convolution operating section 122 comprises delay circuits 122D-1, 122D-2, . . . and 122D-(n−1), multipliers 122A-0, 122A-1, 122A-2, . . . , and 122A-(n−1), and adders 122K-1, 122K2, . . . , and 122K-(n−1). The convolution operating section 122 performs an n-stage convolution.

Delay time T122 for the delay circuits 122D-1, 122D2, . . . , and 122D-(n−1) corresponds to the sampling time Ts for the impulse response waveform. Late reverberation sound data D2 (Lb1, Lb2, . . . , and Lbn) in the reverberation data memory 107 is used as multiplication coefficients for the multiplier 122A-0, 122A-1, 122A-2, . . . , and 122A-(n−1). More specifically, late reverberation sound data Lb1 is used as a multiplication coefficient for the multiplier 122A-0. Late reverberation sound data Lb2 is used as a multiplication coefficient for the multiplier 122A-2, and so on. Late reverberation sound data Lan is used as a multiplication coefficient for the multiplier 122A-(n−1).

The delay circuit 127 delays data for specified period T127. The value of the specified period T127 is adjusted to a value equivalent to a time length (assumed to be the period T1 in the embodiment) of the initial reflection sound data to be convoluted in the convolution operating section 121.

The delay circuit 124 delays data for specified period T124. The value of the specified period T127 is adjusted so as to be larger than the time length of the initial reflection sound data to be convoluted in the convolution operating section 121, i.e., larger than the T1 value (value for the period T127<value for the period T124).

The filter 125 has a feedback loop. The embodiment uses a comb filter as shown in FIG. 22 for the filter 125.

In more detail, the filter 125 is configured by parallel connecting P filters 125F-1, 125F-2, . . . , and 125F-p as shown in FIG. 22. Each filter comprises delay circuits 125D and 125ID, a low-pass filter 125L, amplifiers 125A and 125GA, and an adder 125K. The delay circuit 125ID functions as an initial delay to supply a specified delay for an input signal to the filter 125F-1. The amplifier 125GA provides overall level adjustment for output signals from the filter 125F-1.

The low-pass filter just needs to attenuate a high range. A shelving filter may be used for the low-pass filter.

As mentioned before, FIG. 7 shows the output signal when the filter 125F-I is supplied with a pulse signal. As shown in FIG. 7, the output signal from the filter 125F-1 comprises successive data at an interval of delay time T125 controlled by the delay circuit 125D. When an amplification coefficient of the amplifier 125A is set to a value smaller than 1, the filter 125F-1 can output a signal having natural attenuation characteristics as shown in FIG. 7.

The low-pass filter 125L constituting the filter 125F-1 can remove high-frequency signal components higher than or equal to a specified frequency. Therefore, by adjusting a filter coefficient of the low-pass filter constituting each of the filters 125F-1, 125F-2, . . . , and 125F-p and by adjusting an amplification coefficient of the amplifier 125GA to amplify and output signal from each filter, for example, it is possible to reproduce such acoustic characteristics in an actual acoustic space that a higher frequency signal provides a shorter reverberation time.

As mentioned before, FIG. 8 schematically shows the relationship among an output signal S1 from the convolution operating section 122, output signals S1-1, S1-2, . . . , and S1-p from the filters 125F-1, 125F-2, . . . , and 125F-p, respectively, and an output signal S2 from the filter 125.

The signal S1 is obtained from an operation result of the convolution operating section 122 and is supplied to the filters 125F-1, 125F-2, . . . , and 125F-p. Each filter outputs a signal component by repeatedly attenuating it. The signal component corresponds to the filter coefficient of that filter. The output signals S1-1, S1-2, . . . , and S1-p from the respective filters are synthesized to be the signal S2 which is then output from the filter 125.

That is to say, as shown in FIG. 8, the filter 125 can generate and output the attenuated signal S2 whose period Tf is longer than the period Tc (Tf>Tc) of the signal S1 obtained from the operation result of the convolution operating section 122.

For the sake of convenience, FIG. 8 uses the same signal form for the output signals S1-1, S1-2, . . . , and S1-p from the filters 125F-1, 125F-2 . . . , and 125F-p. Actually, however, the output signals S1-1, S1-2, . . . , and S1-p cause different signal forms (frequency or attenuation characteristics) due to filter coefficient values of the filters 125F-1, 125F-2, . . . , and 125F-p.

The adders 128 and 123 synthesize (add) two supplied signals for output.

The adder 128 outputs a signal by synthesizing a signal obtained from the convolution operating section 121 and a signal obtained from the delay circuit 127. The adder 123 outputs a signal by synthesizing a signal obtained from the adder 128 and a signal output from the filter 125. That is to say, the adder 123 outputs a signal by synthesizing a signal obtained from the convolution operating section 121, a signal obtained from the delay circuit 127, and an output signal from the filter 125.

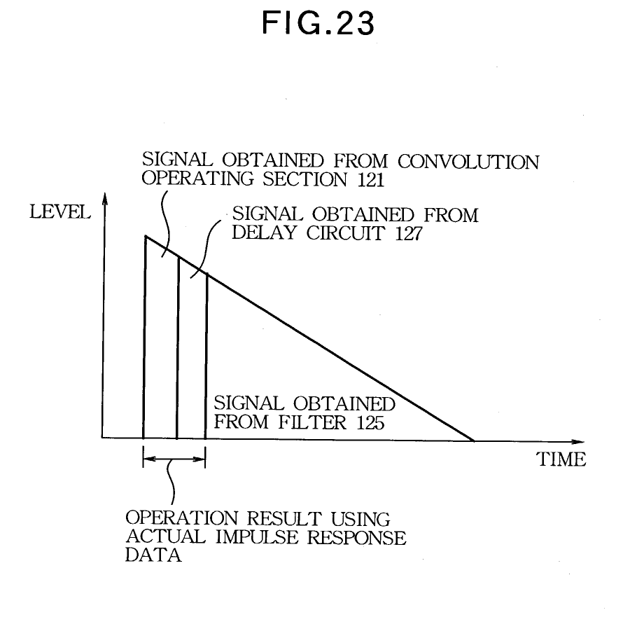

FIG. 23 schematically shows the output signal from the adder 123. According to the second embodiment, as mentioned above, the value of delay time T124 of the delay circuit 127 corresponds to a time length (T1) of the initial reflection sound data convoluted in the convolution operating section 121.

During an impulse response in the reverberation generating section 120, the adder 123 first outputs a signal (initial acoustic signal) obtained from the convolution operating section 121, and then outputs a signal (late acoustic signal) obtained from the convolution operating section 122.

Here, multiplication coefficients used for the convolution operating sections 121 and 122 use data based on impulse response waveforms of the same impulse response. Therefore, natural continuity is ensured between a signal (initial acoustic signal) obtained from the convolution operating section 121 and a signal (late acoustic signal) obtained from the convolution operating section 122. There is no problem of audibly unnatural continuity between data.

The delay time T124 for the delay circuit 124 is adjusted to be longer than the delay time T127 for the delay circuit 127. During an impulse response of the reverberation generating section 120, the adder 123 outputs a signal (late acoustic signal) obtained from the convolution operating section 122, then outputs a signal (reverberation signal) obtained from the filter 125.

Here, the filter 125 generates a reverberation signal by repeatedly attenuating and outputting signals obtained from the convolution operating section 122. Consequently, natural continuity is ensured between the signal (late acoustic signal) obtained from the convolution operating section 122 and the signal (reverberation signal) obtained from the filter 125. There is no problem of audibly unnatural continuity between data.

As mentioned above, during an impulse response of the reverberation generating section 120, the adder 123 outputs a signal by synthesizing the signal (initial acoustic signal) obtained from the convolution operating section 121, the signal (late acoustic signal) obtained from the convolution operating section 122, and the signal (reverberation signal) output from the filter 125. As schematically shown in FIG. 23, the adder 123 outputs an audibly natural signal comprising smoothly continuous data.

Thereafter, the signal (digital signal) output from the adder 123 is supplied to the D/A conversion circuit 108 under control of the CPU 105. The D/A conversion circuit 108 converts the signal into an analog signal which is then output from the speaker 40 via the amplifier 30. The signal is output as a sound provided with the reverberation effect.

The effector 100 according to the present invention uses the convolution operating section 121 to convolute sampling data of the impulse response waveform to generate signals related to the initial reflection sound, wherein the sampling data corresponds to an initial period (e.g., 0 to 0.5 seconds) for a specified time passed after the impulse sound emission.

The effector 100 uses the convolution operating section 121 to convolute sampling data of the impulse response waveform to generate a signal (late acoustic signal) related to the succeeding initial reflection sound, wherein the sampling data corresponds to a second specified period (e.g., 0.3 to 0.5 seconds) after the initial period.

The reverberation generating section 120 according to the second embodiment is configured to output an operation result of the convolution operating section 122 to both the delay circuit 127 and the delay circuit 124 (see FIG. 22). According to this configuration, the operation result of the convolution operating section 122 is not only output intactly as a reverberation generation result from the adder 123, but also provided with attenuation characteristics in the filter 125. That is to say, the late acoustic signal as an operation result of the convolution operating section 122 is used not only as a signal subsequent to the initial acoustic signal, but also as data for generating a reverberation signal.

The acoustic space is characterized by its initial stage. With respect to the acoustic space at its initial stage, the convolution operating sections 121 and 122 produce a convolution result that faithfully reproduces data contents of the impulse response waveform. By using the convolution result as is, it is possible to represent sufficient acoustic characteristics.

The filter outputs a signal by attenuating a convolution result of the convolution operating section 122. This signal is used as a reverberation signal to represent acoustic characteristics for the subsequent acoustic space. Therefore, it is unnecessary to convolute all the sampling data of the impulse response waveform. Sufficient acoustic characteristics can be represented without the need for a large amount of hardware resources.

The generation of reverberation signals is not based on sampling data during the initial reflection sound period that well characterizes the acoustic space and contains a relatively large reflected sound interval, but based on sampling data during the succeeding late reverberation sound period that contains a smaller reflected sound interval. For this reason, it is possible to generate a reverberant sound more faithfully reproducing acoustic characteristics of the impulse response wave.

Further, signals related to the initial reflection sound, the late reverberation sound, and the reverberation sound are generated based on sampling data of the same impulse response waveform. When the adder 123 synthesizes these signals, there is no problem of an unnaturally connected signal. That is to say, it is possible to generate a signal provided with characteristics of the original reverberation space from an input signal.

Since the filter 125 can properly control the contents of reverberation characteristics to be provided, it is possible to freely control the reverberation time by maintaining data contents of the impulse response waveform, in other words, maintaining the acoustic space characteristics.

B: Modifications

There has been described the second embodiment of the present invention. The embodiment is just an example. The present invention may be embodied in various modifications without departing from the spirit and scope of the invention. Available modifications are presented below.

(Modification 1)

The effector 100 according to the second embodiment classifies sampling data of the impulse response waveform into the initial reflection sound data contained in a specified period (0 to 0.3 seconds) from the impulse sound emission and the late reverberation sound data contained in a specified period thereafter (0.3 to 0.5 seconds). These types of data are stored independently. This configuration can be changed in any form. For example, the initial reflection sound data may be contained in a period from 0 to 0.2 seconds. The late reverberation sound data may be contained in a period from 0.2 to 0.5 seconds. That is to say, it is just necessary to ensure continuity between initial reflection sound data and late reverberation sound data in the sampling data of the impulse response waveform. There is no problem of audibly unnatural continuity between data.

(Modification 2)

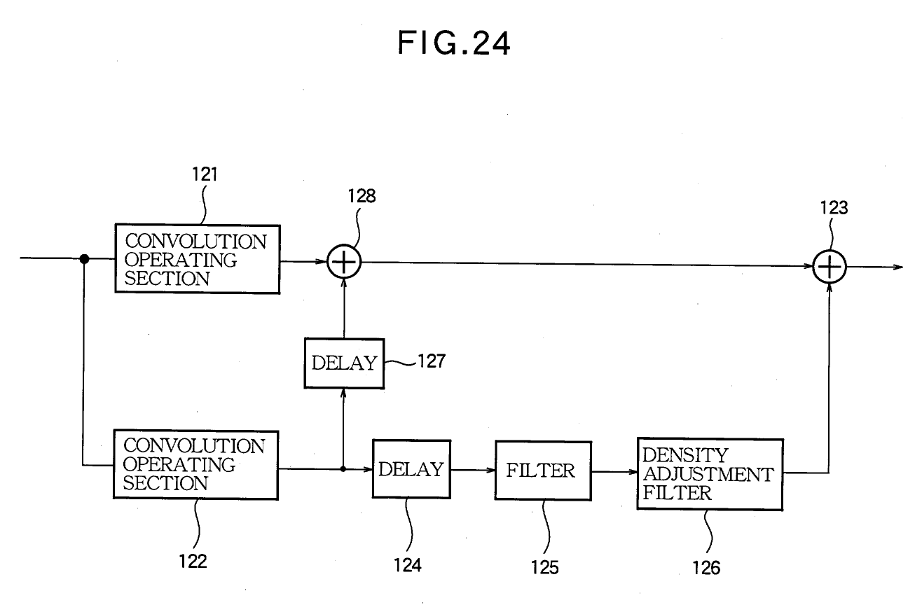

As shown in FIG. 24, the effector may be configured to include a density adjustment filter 126 after the filter 125. The density adjustment filter is used for adjusting (diffusing) data densities (pulse densities) in the time axis direction and data phases (pulse phases).

Here, the purpose of diffusing the data density in the time axis direction takes the following into consideration. Generally, sampling data of the impulse response waveform enters a so-called diffusion area after a sufficient time passes from the point of impulse sound emission. This shortens a time interval to generate data (pulse signal).

Let us assume data phases for the impulse response waveform to be a left-right balance of the human acoustic sense. Then, the purpose of diffusing data phases is to reproduce such acoustic characteristics that data phases show no distinctions after lapse of a sufficient time.

Diffusing data densities and phases makes it possible to simulate the late area (diffusion area) for impulse response in an acoustic space.

As mentioned above, the present invention can control the reverberation time in any manner by maintaining acoustic space characteristics, enabling a simple configuration to provide a sufficient sound field effect.

What is claimed is:

1. An apparatus for applying a reverberation effect to an acoustic signal for output based on sampling data representative of an impulse response waveform, the apparatus comprising:
a first operating section that processes the acoustic signal with sampling data corresponding to an initial period of the impulse response waveform so as to generate an initial acoustic signal, the initial period of the impulse response waveform being determined from a point of impulse sound emission to a point after a lapse of a specified time;
a second operating section that processes the acoustic signal with sampling data corresponding to a selected period of the impulse response waveform so as to generate an additional acoustic signal;
an attenuation operating section that recurrently outputs the additional acoustic signal while attenuating the additional acoustic signal so as to generate a late acoustic signal; and
an output section that synthesizes the initial acoustic signal and the late acoustic signal for the output.

2. The apparatus according to claim 1, wherein the output section synthesizes the initial acoustic signal and the late acoustic signal with a delay therebetween such that the initial acoustic signal smoothly connects to the late acoustic signal.

3. The apparatus according to claim 1, wherein the second operating section processes convolutes the acoustic signal with the sampling data corresponding to the selected period of the impulse response waveform, which is selected subsequently to the initial period from the same impulse response waveform.

4. An apparatus for applying a reverberation effect to an acoustic signal for output based on sampling data representative of an impulse response waveform, the apparatus comprising:
a first operating section that processes the acoustic signal with sampling data corresponding to an initial period of the impulse response waveform so as to generate an initial acoustic signal, the initial period of the impulse response waveform being determined from a point of impulse sound emission to a point after a lapse of a specified time;
a second operating section that processes the acoustic signal with sampling data corresponding to a selected period of the impulse response waveform so as to generate an additional acoustic signal;
an attenuation operating section that recurrently outputs the additional acoustic signal while attenuating the additional acoustic signal so as to generate an attenuating acoustic signal with a certain density and a phase;
a diffusing section that adjusts either of the density and the phase of the attenuating acoustic signal so as to generate a late acoustic signal; and
an output section that synthesizes the initial acoustic signal and the late acoustic signal for the output.

5. The apparatus according to claim 4, wherein the output section synthesizes the initial acoustic signal and the late acoustic signal with a delay therebetween such that the initial acoustic signal smoothly connects to the late acoustic signal.

6. The apparatus according to claim 4, wherein the second operating section processes the acoustic signal with the sampling data corresponding to the selected period of the impulse response waveform, which is selected subsequently to the initial period from the same impulse response waveform.

7. An apparatus for applying a reverberation effect to an acoustic signal for output based on sampling data representative of an impulse response waveform, the apparatus comprising:
a operating section that processes the acoustic signal with sampling data corresponding to an initial period of the impulse response waveform so as to generate an initial acoustic signal, the initial period of the impulse response waveform being determined from a point of impulse sound emission to a point after a lapse of a specified time;
an attenuation operating section that recurrently outputs the initial acoustic signal while attenuating the initial acoustic signal so as to generate a late acoustic signal; and
an output section that synthesizes the initial acoustic signal and the late acoustic signal for the output.

8. The apparatus according to claim 7, wherein the output section synthesizes the initial acoustic signal and the late acoustic signal with a delay therebetween such that the initial acoustic signal smoothly connects to the late acoustic signal.

9. An apparatus for applying a reverberation effect to an acoustic signal for output based on sampling data representative of an impulse response waveform, the apparatus comprising:
a first operating section that processes the acoustic signal with sampling data corresponding to an initial period of the impulse response waveform so as to generate an initial acoustic signal, the initial period of the impulse response waveform being determined between a point of impulse sound emission and a first point after a lapse of a specified time;
a second operating section that processes the acoustic signal with sampling data corresponding to a subsequent period of the impulse response waveform so as to generate a late acoustic signal, the subsequent period of the impulse response waveform being determined between the first point and a second point after a lapse of another specified time;
an attenuation operating section that recurrently outputs the late acoustic signal while attenuating the late acoustic signal so as to generate a reverberation signal; and
an output section that synthesizes the initial acoustic signal, the late acoustic signal and the reverberation signal for the output.

10. The apparatus according to claim 9, further comprising a storage section that stores the sampling data corresponding to the initial period of the impulse response waveform for feeding the first convoluting operation section and the sampling data corresponding to the subsequent period of the same impulse response waveform for feeding the second convoluting operation section.

11. The apparatus according to claim 9, wherein the output section synthesizes the initial acoustic signal and the late acoustic signal with a delay therebetween such that the initial acoustic signal smoothly connects to the late acoustic signal.

12. An apparatus for applying a reverberation effect to an acoustic signal for output based on sampling data representative of an impulse response waveform, the apparatus comprising:
a first operating section that processes the acoustic signal with sampling data corresponding to an initial period of the impulse response waveform so as to generate an initial acoustic signal, the initial period of the impulse response waveform being determined between a point of impulse sound emission and a first point after a lapse of a specified time;
a second operating section that processes the acoustic signal with sampling data corresponding to a subsequent period of the impulse response waveform so as to generate a late acoustic signal, the subsequent period of the impulse response waveform being determined between the first point and a second point after a lapse of another specified time;
an attenuation operating section that recurrently outputs the late acoustic signal while attenuating the late acoustic signal so as to generate an attenuating acoustic signal with a certain density and a phase;
a diffusing section that adjusts either of the density and the phase of the attenuating acoustic signal so as to generate a reverberation signal; and
an output section that synthesizes the initial acoustic signal, the late acoustic signal and the reverberation signal for the output.

13. The apparatus according to claim 12, further comprising a storage section that stores the sampling data corresponding to the initial period of the impulse response waveform for feeding the first convoluting operation section and the sampling data corresponding to the subsequent period of the same impulse response waveform for feeding the second convoluting operation section.

14. The apparatus according to claim 12, wherein the output section synthesizes the initial acoustic signal and the late acoustic signal with a delay therebetween such that the initial acoustic signal smoothly connects to the late acoustic signal.

15. A method of applying a reverberation effect to an acoustic signal for output based on sampling data representative of an impulse response waveform, the method comprising:
a first operating step of processing the acoustic signal with sampling data corresponding to an initial period of the impulse response waveform so as to generate an initial acoustic signal, the initial period of the impulse response waveform being determined from a point of impulse sound emission to a point after a lapse of a specified time;
a second operating step of processing the acoustic signal with sampling data corresponding to a selected period of the impulse response waveform so as to generate an additional acoustic signal;
an attenuation operating step of recurrently outputting the additional acoustic signal while attenuating the additional acoustic signal so as to generate a late acoustic signal; and
an output step of synthesizing the initial acoustic signal and the late acoustic signal for the output.

16. A method of applying a reverberation effect to an acoustic signal for output based on sampling data representative of an impulse response waveform, the method comprising:
a first operating step of processing the acoustic signal with sampling data corresponding to an initial period of the impulse response waveform so as to generate an initial acoustic signal, the initial period of the impulse response waveform being determined from a point of impulse sound emission to a point after a lapse of a specified time;
a second operating step of processing the acoustic signal with sampling data corresponding to a selected period of the impulse response waveform so as to generate an additional acoustic signal;
an attenuation operating step of recurrently outputting the additional acoustic signal while attenuating the additional acoustic signal so as to generate an attenuating acoustic signal with a certain density and a phase;
a diffusing step of adjusting either of the density and the phase of the attenuating acoustic signal so as to generate a late acoustic signal; and
an output step of synthesizing the initial acoustic signal and the late acoustic signal for the output.

17. A method of applying a reverberation effect to an acoustic signal for output based on sampling data representative of an impulse response waveform, the method comprising:
a first operating step of processing the acoustic signal with sampling data corresponding to an initial period of the impulse response waveform so as to generate an initial acoustic signal, the initial period of the impulse response waveform being determined between a point of impulse sound emission and a first point after a lapse of a specified time;
a second operating step of processing the acoustic signal with sampling data corresponding to a subsequent period of the impulse response waveform so as to generate a late acoustic signal, the subsequent period of the impulse response waveform being determined between the first point and a second point after a lapse of another specified time;
an attenuation operating step of recurrently outputting the late acoustic signal while attenuating the late acoustic signal so as to generate a reverberation signal; and
an output step of synthesizing the initial acoustic signal, the late acoustic signal and the reverberation signal for the output.

18. A method of applying a reverberation effect to an acoustic signal for output based on sampling data representative of an impulse response waveform, the method comprising:
a first operating step of processing the acoustic signal with sampling data corresponding to an initial period of the impulse response waveform so as to generate an initial acoustic signal, the initial period of the impulse response waveform being determined between a point of impulse sound emission and a first point after a lapse of a specified time;
a second operating step of processing the acoustic signal with sampling data corresponding to a subsequent period of the impulse response waveform so as to generate a late acoustic signal, the subsequent period of the impulse response waveform being determined between the first point and a second point after a lapse of another specified time;
an attenuation operating step of recurrently outputting the late acoustic signal while attenuating the late acoustic signal so as to generate an attenuating acoustic signal with a certain density and a phase;
a diffusing step of adjusting either of the density and the phase of the attenuating acoustic signal so as to generate a reverberation signal; and
an output step of synthesizing the initial acoustic signal, the late acoustic signal and the reverberation signal for the output.

19. A program for use in an apparatus having a CPU and applying a reverberation effect to an acoustic signal for output based on sampling data representative of an impulse response waveform, the program being executable by the CPU for causing the apparatus to perform a method comprising:
a first operating step of processing the acoustic signal with sampling data corresponding to an initial period of the impulse response waveform so as to generate an initial acoustic signal, the initial period of the impulse response waveform being determined from a point of impulse sound emission to a point after a lapse of a specified time;
a second operating step of processing the acoustic signal with sampling data corresponding to a selected period of the impulse response waveform so as to generate an additional acoustic signal;
an attenuation operating step of recurrently outputting the additional acoustic signal while attenuating the additional acoustic signal so as to generate a late acoustic signal; and
an output step of synthesizing the initial acoustic signal and the late acoustic signal for the output.

20. A computer-readable medium storing the program according to claim 19.

21. A program for use in an apparatus having a CPU and applying a reverberation effect to an acoustic signal for output based on sampling data representative of an impulse response waveform, the program being executable by the CPU for causing the apparatus to perform a method comprising:
a first operating step of processing the acoustic signal with sampling data corresponding to an initial period of the impulse response waveform so as to generate an initial acoustic signal, the initial period of the impulse response waveform being determined from a point of impulse sound emission to a point after a lapse of a specified time;
a second operating step of processing the acoustic signal with sampling data corresponding to a selected period of the impulse response waveform so as to generate an additional acoustic signal;
an attenuation operating step of recurrently outputting the additional acoustic signal while attenuating the additional acoustic signal so as to generate an attenuating acoustic signal with a certain density and a phase;
a diffusing step of adjusting either of the density and the phase of the attenuating acoustic signal so as to generate a late acoustic signal; and
an output step of synthesizing the initial acoustic signal and the late acoustic signal for the output.

22. A computer-readable medium storing the program according to claim 21.

23. A program for use in an apparatus having a CPU and applying a reverberation effect to an acoustic signal for output based on sampling data representative of an impulse response waveform, the program being executable by the CPU for causing the apparatus to perform a method comprising:
a first operating step of processing the acoustic signal with sampling data corresponding to an initial period of the impulse response waveform so as to generate an initial acoustic signal, the initial period of the impulse response waveform being determined between a point of impulse sound emission and a first point after a lapse of a specified time;
a second operating step of processing the acoustic signal with sampling data corresponding to a subsequent period of the impulse response waveform so as to generate a late acoustic signal, the subsequent period of the impulse response waveform being determined between the first point and a second point after a lapse of another specified time;
an attenuation operating step of recurrently outputting the late acoustic signal while attenuating the late acoustic signal so as to generate a reverberation signal; and
an output step of synthesizing the initial acoustic signal, the late acoustic signal and the reverberation signal for the output.

24. A computer-readable medium storing the program according to claim 23.

25. A program for use in an apparatus having a CPU and applying a reverberation effect to an acoustic signal for output based on sampling data representative of an impulse response waveform, the program being executable by the CPU for causing the apparatus to perform a method comprising:
a first operating step of processing the acoustic signal with sampling data corresponding to an initial period of the impulse response waveform so as to generate an initial acoustic signal, the initial period of the impulse response waveform being determined between a point of impulse sound emission and a first point after a lapse of a specified time;
a second operating step of processing the acoustic signal with sampling data corresponding to a subsequent period of the impulse response waveform so as to generate a late acoustic signal, the subsequent period of the impulse response waveform being determined between the first point and a second point after a lapse of another specified time;
an attenuation operating step of recurrently outputting the late acoustic signal while attenuating the late acoustic signal so as to generate an attenuating acoustic signal with a certain density and a phase;
a diffusing step of adjusting either of the density and the phase of the attenuating acoustic signal so as to generate a reverberation signal; and
an output step of synthesizing the initial acoustic signal, the late acoustic signal and the reverberation signal for the output.

26. A computer-readable medium storing the program according to claim 25.
